(19) United States
(12) Patent Application Publication
(10) Pub. No.: US 2016/0023905 A1
(43) Pub. Date: Jan. 28, 2016

(54) CARBON NANO-TUBE PRODUCTION FROM CARBON DIOXIDE

(71) Applicant: SAUDI BASIC INDUSTRIES CORPORATION, Riyadh (SA)

(72) Inventor: Chu Wei, Riyadh (SA)

(73) Assignee: SAUDI BASIC INDUSTRIES CORPORATION, Riyadh (SA)

(21) Appl. No.: 14/760,701

(22) PCT Filed: Jan. 15, 2014
(86) PCT No.: PCT/IB2014/058298

§ 371 Date: Jul. 13, 2015

Related U.S. Application Data
(60) Provisional application No. 61/753,488, filed on Jan. 17, 2013.

(51) Int. Cl. C01B 31/02; C23C 16/448; C23C 16/26; C01B 31/00

(52) U.S. Cl. CPC C01B 31/0233; C01B 31/00; C23C 16/4488; C23C 16/26; C01B 2202/06; C01B 2202/02; C01B 2202/36

(57) ABSTRACT

Disclosed is a method for making carbon nanotubes comprising (a) reducing a nickel containing catalyst with a reducing agent in a first reaction chamber, (b) contacting the nickel containing catalyst with carbon dioxide under conditions sufficient to produce a reaction product, (c) transferring the reaction product to a second reaction chamber, wherein the second reaction chamber comprises a Group VIII metal containing catalyst, and (d) contacting the Group VIII metal containing catalyst with the reaction product under conditions sufficient to produce carbon nanotubes, wherein the first and second reaction chambers are in flow connection during the transfer step (c), wherein the only source of carbon used to form the carbon nanotubes is from the carbon dioxide used in step (b), and wherein at least 20% of the carbon from the carbon dioxide used in step (b) is converted into carbon nanotubes.

### BACKGROUND OF THE INVENTION

A. Field of the Invention

The present invention relates to methods for producing carbon nanotubes from carbon dioxide.

B. Description of Related Art

Carbon nanotubes have previously been characterized as allotropes of carbon with a cylindrical nanostructure. These structures are valuable for nanotechnology, electronics, optics and other fields of materials science and technology. For instance, carbon nanotubes have been incorporated into a variety of products (e.g., nanotube-based transistors, circuits, cables, wires, batteries, solar cells, baseball bats, golf clubs, car parts etc.).

One of the problems, however, has been to identify an efficient process by which to produce carbon nanotubes. For instance, several processes utilize methane as the direct carbon source. Unfortunately, methane as a direct source can be relatively expensive.

Another reported process is to decompose carbon dioxide into carbon monoxide followed by conversion of the carbon monoxide into carbon nanotubes (see WO 2009/011984). Such a process, however, oftentimes fails to efficiently decompose the carbon dioxide, which leaves a substantial amount of carbon dioxide as a by-product. This can be undesirable given the potential links between carbon dioxide emissions and global warming and may further require a second pass through or sequestration of the carbon dioxide, both of which add to the complexity of the process.

Other processes that attempt to directly convert carbon dioxide to carbon nanotubes on a single catalytic substrate have also been attempted (U.S. Pat. No. 6,261,532). Such processes, however, oftentimes fail to efficiently utilize the carbon dioxide and can lead to problems such as those discussed above.

### SUMMARY OF THE INVENTION

The present invention provides a solution to the current problems facing the production of carbon nanotubes. The solution is premised on the use of a new chemical vapor deposition integrated process (referenced throughout as “CVD-IP”) that utilizes two reaction chambers which are connected to one another (e.g., in flow connection from the first chamber to the second chamber; a valve could be used to separate the two chambers). In the first reaction chamber the carbon dioxide can be converted into methane. In the second reaction chamber carbon nanotubes can be produced from the formed methane using a chemical vapor deposition process. As illustrated in the Examples, this process can result in a high carbon dioxide conversion rate (e.g., upwards of nearly 100%) and a carbon-based yield of carbon nanotubes that is at least 20, 25, 30, 35, or 40% or more, neither of which has been achieved in current carbon nanotube processes that utilize carbon dioxide as the direct carbon source. Even more, these results can be achieved with a single pass-through or run through of the process. Multiple runs utilizing the original starting carbon source (e.g., carbon dioxide) do not have to be performed to achieve these conversion and yield rates.

While keeping this, in one aspect of the present invention there is disclosed a method for making carbon nanotubes comprising (a) reducing a nickel containing catalyst with a reducing agent in a first reaction chamber, (b) contacting the nickel containing catalyst with carbon dioxide under conditions sufficient to produce a reaction product, (c) transferring the reaction product to a second reaction chamber, wherein the second reaction chamber comprises a Group VIII metal containing catalyst, and (d) contacting the Group VIII metal containing catalyst with the reaction product under conditions sufficient to produce carbon nanotubes, wherein the first and second reaction chambers are in flow connection during the transfer step (c), wherein the only source of carbon used to form the carbon nanotubes is from the carbon dioxide used in step (b), and wherein at least 20% of the carbon from the carbon dioxide used in step (b) is converted into carbon nanotubes. In some instances, at least 20, 25, 30, 35, 40, 50, 60, 70, 80, 90, 95, or about 100% of the carbon (e.g., from the carbon dioxide introduced into the first reaction chamber is converted into carbon nanotubes). In some instances, the reducing agent is hydrogen gas. The nickel containing catalyst can be supported by a metal oxide or oxide carrier such as those described throughout the specification. For instance, the metal oxide can be selected from the group consisting of silicon dioxide, aluminum oxide, a rare earth metal oxide, a modified aluminum oxide, and mixtures thereof. The oxide carrier can be selected from the group consisting of magnesium oxide, calcium oxide, other alkali-earth oxide, zinc oxide, zirconium oxide, titanium oxide, and mixture thereof. The Group VIII metal containing catalyst can be a nickel, cobalt, or iron containing catalyst or a composite thereof. Step (b) can be performed in the presence of hydrogen. The reaction product can include methane. In certain aspects, the reaction product includes at least 50, 60, 70, 80, 90, 95, or about 100% methane in carbon-base, which illustrates the efficiency of the process of the present invention to convert the starting material, carbon dioxide, into a reaction product (e.g., methane) that is ultimately converted into carbon nanotubes. In some instances, the reaction product from the first reaction chamber can include any one of, any combination of, carbon dioxide, hydrogen, water, or carbon monoxide. The amounts of these additional reaction products can be relatively minimal (e.g., less than 5 4, 3, 2, 1% by total combined weight) to non-existent. Step (b) can be performed at a temperature ranging from about 200, 250, 300, 350, 400, 450, to 500° C., or from about 260° C. to about 460° C., or from about 300° C. to 380 C. Step (d) can be performed at a temperature ranging from about 500, 550, 600, 650, 700, 750, 800, 850, or 900° C., or from about 600° C. to about 800° C., or from about 650° C. to about 750° C. In some instances, the carbon dioxide is introduced into the first reaction chamber at a flow rate of about 1 milliliter per minute (ml/min), 2 ml/min, 3 ml/min, 4 ml/min, 5 ml/min, 6 ml/min, 7 ml/min, 8 ml/min, 9 ml/min, 10 ml/min, 15 ml/min, 20 ml/min, 25 ml/min, 30 ml/min, 40 ml/min, 45 ml/min, 50 ml/min, 55 ml/min, 60 ml/min, 65 ml/min, 70 ml/min, 75 ml/min, 80 ml/min, 85 ml/min, 90 ml/min, 95 ml/min, or 100 or more ml/min. In certain aspects, the flow rate ranges from about 5 ml/min to 60 ml/min or from about 10 ml/min to about 50 ml/min or from about 15 ml/min to about 45 ml/min, or from about 20 ml/min to about 40 ml/min, or from about 25 ml/min to about 35 ml/min. The carbon nanotubes produced from the process can be multi-wall or single-wall carbon nanotubes or mixtures thereof. In some instances, the majority of the carbon nanotubes have closed tube ends. The outer diameter of the carbon nanotubes can range, for example, from about 15 to 25 nanometers (nm) or 19 nm to 21 nm. The thickness of the carbon nanotube walls can range from about 1 to 10 nm or 4 nm to 7 nm. The inner diameter of the carbon nanotubes can range from about 5 to 15 nm or 7 nm to 10 nm. In some instances, steps (b), (c), or (d), or any combination thereof or all of said steps, can be performed in the presence of additional water. In particular instances, step (d) can be performed in the presence of additional water. The additional water can be added in the form of water vapor. In one aspect, the reaction product is fed through water vapor prior to entering the second reaction chamber. In one aspect, the reaction product is fed through water vapor after the reaction product leaves the first reaction chamber. In one aspect, the reaction product is fed through water vapor after the reaction product leaves the first reaction chamber and prior to entering the second reaction chamber. In one aspect, the reaction product is fed through water vapor in the first reaction chamber or in the second reaction chamber or both chambers. The water vapor can be supplied by a water vaporator or bubbler such that the reaction product is fed through said vaporator or bubbler. In certain aspects, the water vapor is at around room temperature (e.g., about 20 to 25° C.). The water vapor pressure can be about 1 kiloPascals (kPa), 2 kPa, 3 kPa, 4 kPa, 5 kPa, 6 kPa, 7 kPa, 8 kPa, 9 kPa, 10 kPa, 15 kPa, 20 kPa, or more. In certain aspects, the water vapor pressure can be between about 1 to 10 kPa or about 1 to 5 kPa or around 2.81 kPa. Once the reaction product is fed through the water vapor, the amount of water present in the reaction product can be about 1, 2, 3, 4, 5, 6, 7, 8, 9, 10, 11, 12, 13, 14, 15, 20% or more by molar volume of the reaction product or about 1% to about 10% or about 1% to about 5% by molar volume of the reaction product. It was discovered by the inventor that when water-vapor is used, the quantity of water can affect the yield of the carbon nanotubes. Further, the presence of water within the reaction product can lead to the formation of carbon nanotubes more open ends, which can improve the arrangement or packing of said carbon nanotubes (e.g., more orderly packing) and can also improve the morphology of the carbon nanotubes. In some instances (e.g., when water vapor is used), the outer diameter of the carbon nanotubes can range from about 15 to 25 nm or 19 nm to 21 nm. The thickness of the carbon nanotube walls can range from about 5 to about 15 nm or 7 nm to 9 nm. The inner diameter of the carbon nanotubes can range from about 1 to 10 nm or about 3 nm to 5 nm. In one aspect, the carbon dioxide in step (b) is the starting material used to produce the carbon nanotubes. In some aspects, carbon dioxide is the sole source of carbon used to product the carbon nanotubes (e.g., while other carbon materials are produced during the reaction (e.g., methane), the starting material or starting carbon source can be limited to carbon dioxide). In other aspects, the carbon dioxide in step (b) is 80, 90, 95, 96, 97, 98, 99, or 100% of the carbon source that is used to produce the carbon nanotubes, which allows for other carbon materials (e.g., methane, carbon monoxide, etc.) to be used along with carbon dioxide as the starting material.

Carbon nanotubes produced by the processes disclosed throughout this specification can have a number of uses. For instances, that can be used in a variety of different technology fields such as for nanotechnology, electronics, optics and other fields of materials science and technology. Non-limiting examples of products that can include carbon nanotubes produced by the processes of the present invention include nanotube-based transistors, circuits, cables, wires, batteries, solar cells, baseball bats, golf clubs, car parts etc.

“Inhibiting” or “reducing” or any variation of these terms, when used in the claims or the specification includes any measurable decrease or complete inhibition to achieve a desired result.

“Effective” or “treating” or “preventing” or any variation of these terms, when used in the claims or specification, means adequate to accomplish a desired, expected, or intended result.

The term “about” or “approximately” are defined as being close to as understood by one of ordinary skill in the art, and in one non-limiting embodiment the terms are defined to be within 10%, preferably within 5%, more preferably within 1%, and most preferably within 0.5%.

In some instances water can be used as an additive in the processes of the present invention. The water can be added in the form of water vapor. In other instances, however, water may not be introduced into the process as an additive, such that the process is “water-free.” Water-free can include instances where the reaction product is not processed through or fed through water vapor and the reaction product includes less than 1, 0.5, 0.1, or 0.01% by weight or volume of water before being transferred into the second reaction chamber.

“Water vapor” is water in a gaseous or vaporous state at a temperature below the boiling point of water.

The use of the word “a” or “an” when used in conjunction with the term “comprising” in the claims or the specification may mean “one,” but it is also consistent with the meaning of “one or more,” “at least one,” and “one or more than one.”

The words “comprising” (and any form of comprising, such as “comprise” and “comprises”), “having” (and any form of having, such as “have” and “has”), “including” (and any form of including, such as “includes” and “include”) or “containing” (and any form of containing, such as “contains” and “contain”) are inclusive or open-ended and do not exclude additional, unrecited elements or method steps.

The methods, ingredients, components, compositions, etc. of the present invention can “comprise,” “consist essentially of,” or “consist of” particular method steps, ingredients, components, compositions, etc. disclosed throughout the specification. With respect to the transitional phase “consisting essentially of,” in one non-limiting aspect, a basic and novel characteristic of the processes of the present invention is a high carbon dioxide conversion rate (e.g., upwards of 80%, 90%, 95%, or nearly 100%) and a carbon nanotube yield rate that is greater than 20% or even more than 30% can be achieved from the starting carbon source (e.g., carbon dioxide).

Other objects, features and advantages of the present invention will become apparent from the following figures, detailed description, and examples. It should be understood, however, that the figures, detailed description, and examples, while indicating specific embodiments of the invention, are given by way of illustration only. Additionally, it is contemplated that changes and modifications within the spirit and scope of the invention will become apparent to those skilled in the art from the detailed description.

### BRIEF DESCRIPTION OF THE DRAWINGS

FIG. 1: A schematic illustration of a CVD-IP process of the present invention.

FIG. 2: TEM/HRTEM images of carbon dioxide-derived carbon nanotubes (referenced as “CNT-C1”) from carbon dioxide catalytic conversion (referenced as “CVD-IP1”).

FIG. 3: HRTEM image of carbon dioxide-derived carbon nanotubes (referenced as “CNT-C2”) from carbon dioxide catalytic conversion (referenced as “CVD-IP2”) (10 nm scale).

FIG. 4: TEM image of carbon dioxide-derived carbon nanotubes (CNT-C2) from carbon dioxide catalytic conversion (CVD-IP2) (100 nm scale).

FIG. 5: TEM image of carbon dioxide-derived carbon nanotubes (CNT-C2) from carbon dioxide catalytic conversion (CVD-IP2) (200 nm scale).

FIG. 6: TEM image of carbon dioxide-derived carbon nanotubes (CNT-C2) from carbon dioxide catalytic conversion (CVD-IP2) (200 nm scale).

FIG. 7: TEM image of carbon dioxide-derived carbon nanotubes (CNT-C2) from carbon dioxide catalytic conversion (CVD-IP2) (500 nm scale).

FIG. 8: TEM image of carbon dioxide-derived carbon nanotubes (CNT-C2) from carbon dioxide catalytic conversion (CVD-IP2) (200 nm scale).

FIG. 9 (a), (b): GC profiles of gas-phase outlet mixture vs reaction time on stream.

FIG. 10: Raman spectra for CNTs products over the 303# catalyst at several conditions: (a) 600 C; (b) 700 C; (c) 800 C; (d) 700 C for water-assisted CNTs.

FIG. 11: SEM image of CNTs prepared using CVD-IP method over Ni-A303 catalyst: (a) water-free process; (b) water-assisted process.

### DESCRIPTION OF ILLUSTRATIVE EMBODIMENTS

As discussed above, the current reported methods for producing carbon nanotubes can be inefficient and can result in excess carbon dioxide as a by-product (see Motiei M, Hacohen Y R, Calderon-Moreno J, Gedanken A. Preparing Carbon Nanotubes and Nested Fullerenes from Supercritical CO2 by a Chemical Reaction. J Am Chem Soc, 2001, 123 (35): 8624-8625, which is incorporated by reference, which used supercritical carbon dioxide with Mg metal under severe conditions (e.g., temperature of 1000° C. and high pressure). Similarly, Lou et al. (2003) and (2006) (see Lou Z, Chen Q, Wang W, Zhang Y. Synthesis of carbon nanotubes by reduction of carbon dioxide with metallic lithium. Carbon, 2003, 41: 3063-3074; and Lou Z, Chen C, Huang H, Zhao D. Fabrication of Y-junction carbon nanotubes by reduction of carbon dioxide with sodium borohydride. Diamond Relat Mater, 2006, 15: 1540-1543, both of which are incorporated by reference) used supercritical carbon dioxide as carbon source and alkali metals Li or NaBH₄ as the reductants to synthesize carbon dioxide under reaction temperatures of 600-750° C. However the yield from carbon dioxide to carbon nanotubes was estimated as only about 5% or less. Further, the use of supercritical carbon dioxide requires special equipment that can withstand abnormally high pressure.

By comparison, the processes of the present invention can result in a high carbon dioxide conversion rate (e.g., 80, 85, 90, 95, to about 100%) and a carbon nanotube yield rate from the starting carbon source (e.g., carbon dioxide) that can be about at least 20, 25, 30, 35, 40% or more. These results can be achieved with a single pass-through or run through of the process without having to perform multiple pass through runs. Further, these results, confirm the efficiency of the processes of the present invention when compared to currently known processes that suffer from low carbon dioxide conversion rates, low carbon nanotube yield rates, and the use of severe reaction conditions (e.g., high temperatures of 1000° C. and high pressure used with supercritical carbon dioxide).

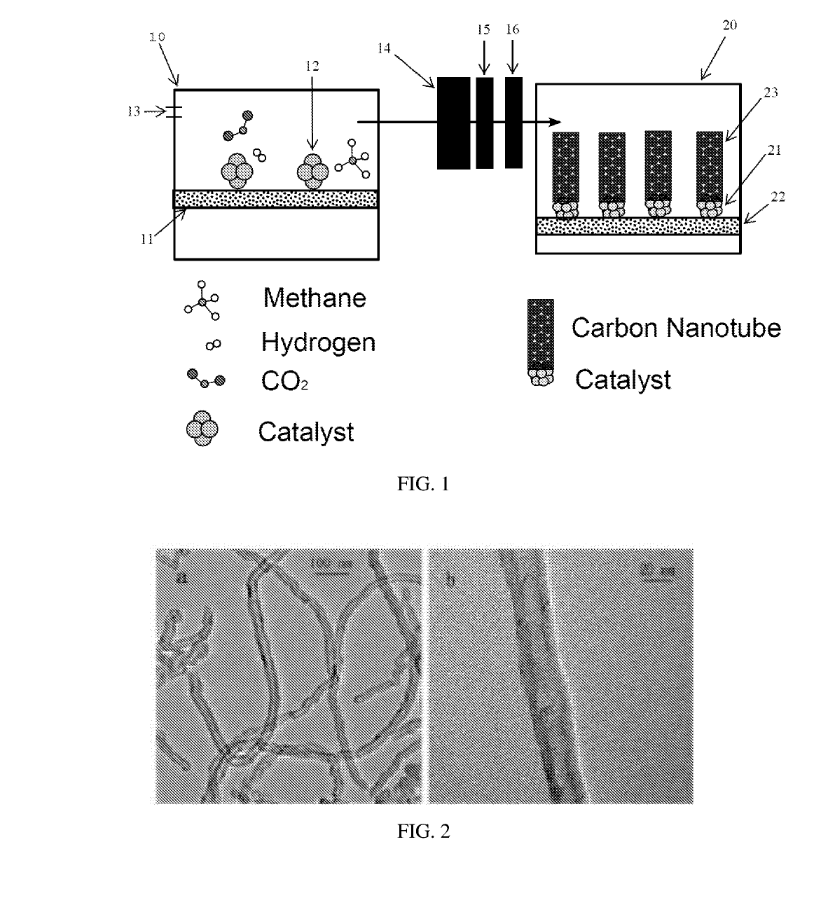

FIG. 1 provides a schematic overview of a process of the present invention. A first reaction chamber 10 can include a support 11, a catalyst 12 that can be used to convert carbon dioxide to methane, and a gas inlet 13. In one non-limiting aspect, the reaction chamber 10 can be a quartz reaction chamber or a glass reaction chamber or a stainless steel reaction chamber. The support 11 can be a common carrier such as silica, alumina, rare earth oxide metal (e.g., Y₂O₃, La₂O₃), or a modified alumina. Further, a promoter such as MgO, TiO₂, ZrO₂, CeO₂, La₂O₃, Y₂O₃, or mixtures thereof could be used to enhance the dispersion and reducibility of the catalyst 12. As for the catalyst 12, it has been discovered by the inventor that a nickel containing catalyst resulted in the higher carbon dioxide conversion rate and carbon nanotube yield rate. An example of a nickel containing catalyst in the first reaction chamber includes a supported nickel oxide catalyst or a nickel-iron catalyst, such as Ni-A1-Al₂O₃ (“Ni-A101 catalyst”). “A1” can be a promoter such as Y, Zr, Ce, La, or Fe, Cu. The gas inlet 13 can be used to introduce gaseous substances such as carbon dioxide, hydrogen into the first reaction chamber 10. The first reaction chamber 10 can be connected to a second reaction chamber 20 by, for example, a valve 14 such that when the valve 14 is switched for connection/opened, the first 10 and second 20 reaction chambers can be in flow connection or communication with one another so as to allow the reaction products from the first reaction chamber 10 to enter into the second reaction chamber 20. Although not required, the outlet mixture of the first reaction chamber 10 can be processed through a silica gel trap 15 to remove water (e.g., less than 1, 0.5, 0.1, or 0.01% by weight or volume of water remains in reaction product) (see Examples), and then can be introduced into the second reaction chamber 20 (e.g., via an inox (stainess steel) pipeline). Alternatively, the outlet mixture of the first reaction chamber 10 can be processed through a water vaporator or bubbler 16 so as to introduce external water into the process as an additive. The pressure of the water vapor can be modified by temperature, which can have the effect of increasing or decreasing the amount of water imparted to the reaction product. For instance, and as noted above, once the reaction product is fed through the water vapor, the amount of water present in the reaction product can be about 1, 2, 3, 4, 5, 6, 7, 8, 9, 10, 11, 12, 13, 14, 15, 20% or more by molar volume of the reaction product or about 1% to about 10% or about 1% to about 5% by molar volume of the reaction product. The amount of water present within said reaction product can be modified by increasing or decreasing the water vapor pressure (e.g., by temperature). This discovery by the inventor of using water as an additive is advantageous in several respects. First, caustic acids such as nitric acid are not needed to form open-ended tubes. Further, the produced carbon nanotubes had improved spacial arrangement or packing (e.g., more orderly packing) and also had improved morphology.

The second reaction chamber 20 can include a catalyst 21 with a support 22 for the catalyst 21 allowing for the formation of carbon nanotubes 23. The catalyst 21 can be a Group VIII metal containing catalyst such as nickel, colbalt, iron, or mixtures thereof (e.g., one a Ni-A202 catalyst can be Ni-A2-MgO; another catalyst Ni-A303 can be Ni-A3-La₂O₃). The support 22 can be a common carrier such as silica, alumina, rare earth oxide metal such as yttrium oxide or cerium oxide, or a modified alumina. The second reaction chamber 20 can be, for example, a quartz reaction chamber which allows operations at higher temperature (600 to 800° C.).

### EXAMPLES

The present invention will be described in greater detail by way of specific examples. The following examples are offered for illustrative purposes, and are not intended to limit the invention in any manner. Those of skill in the art will readily recognize a variety of noncritical parameters which can be changed or modified to yield essentially the same results.

### Example 1

### Carbon Dioxide Conversion and Carbon Nanotube Production

Example 1 references FIG. 1 for illustrative purposes. A nickel-based catalyst 12 was synthesized by a citric acid combustion method to produce powders (see Ran M F, Liu Y, Chu W, Liu Z B, Borgna A. Catal Commun, 2012, 27: 69; Ran M F, Sun W J, Liu Y, Chu W, Jiang C F. J Solid State Chem, 2013, 197: 517; Wen J, Chu W, Jiang C F, Tong D G. J Nat Gas Chem, 2010, 19(2): 156, both of which are incorporated by reference). 500 milligrams (mg) of the catalyst 12 was placed in a ceramic boat 11. The ceramic boat 11 was placed into a quartz reactor 10. The catalyst 12 was reduced in the presence of pure hydrogen at a temperature of 550° C. for a period of 120 minutes. Pure carbon dioxide was fed into the quartz reactor 10 at a flow rate of 15 ml/min or 30 ml/min and hydrogenated to methane and water at a temperature of 300-380° C. for a period of 120 minutes to 360 minutes. The inlet hydrogen flowrate was at about the stoichiometric ratio (4 times, i.e., 60 ml/min or 120 ml/min). The outlet mixture of reaction chamber 10 including the formed methane was then transferred into the second reaction chamber 20 (the second reaction chamber was a quartz type reactor). The reaction in the second reaction chamber 20 used a nickel-iron catalyst or a nickel-based catalyst (Ni-A202=Ni-A2-MgO) at a temperature of 600 C to 800° C. and for 120 minutes or 360 minutes. A carbon dioxide-derived carbon nanotube sample of type I (“CNT-C1”) was obtained. The following chemical reactions occurred:

nCO₂+4nH₂→nCH₄+2nH₂O (1)

nCH₄→Carbon Nanotubes (CNTs)+2nH₂ (2)

In total, the net reaction is:

nCO₂+2nH₂→CNTs+2nH₂O (3)

The process in the above paragraph (referred to as “CVD-IP1”) was repeated with one difference. Water (in the form of water vapor) was added during the transferring step from the outlet of the first reaction chamber into the second reaction chamber. This was done by feeding the reaction material into a water vapor saturator, in which the water vapor was at room temperature (at 23 C, about 2.8%). This enhanced process with the addition of water vapor process (referred to as “CVD-IP2”) resulted in the production of carbon nanotubes of type II (“CNT-C2”).

For comparison, conventional carbon nanotubes were prepared via a CVD method from methane raw material using Ni-based or Ni—Fe-based catalyst (the carbon-product was labeled like “CNT-M1”), as described in J. Wen, W. Chu, C. F. Jiang and D. G. Tong, J Nat Gas Chem, 2010, 19, 156, which is incorporated by reference. CNT-M1 was further purified using concentrated HNO₃ (68 wt %) and refluxed at 140° C. for 12 hours in an oil bath. This purified carbon-sample was labeled CNT-M2. The primary four carbon nanotubes (CNTs) samples are listed in Table 1, with the CNT-C1 and CNT-C2 carbon nanotubes being produced from the processes according to the present invention (e.g., CVD-IP1 and CVD-IP2):

TABLE 1
(CNTs samples and relative conditions)

| Sample Code | Raw Carbon Material | Synthesis Method |
|---|---|---|
| CNT-C1 | CO₂ derived | CVD-IP1 |
| CNT-C2 | CO₂ derived | CVD-IP2 |
| CNT-M1 | CH₄ derived | CVD |
| CNT-M2 | CH₄ derived | CVD |

The “productivity of CNTs” was calculated using the following equation:

Productivity of CNTs=(mₜₒₜ−m_{cat})/m_{cat}×100(%)

where m_{cat} was the catalyst mass before reaction, and mₜₒₜ was the total mass of the solid-form carbon product with the catalyst, after six-hours reaction of catalytic conversion of carbon dioxide producing the solid-state carbon-materials.

### Example 2

### Characterization of the CO2 Derived CNT Samples and Results

The samples in Table 1 were characterized by several techniques using XRD, TEM, FT-IR, TG-DTG, etc. (see A. Y. Khodakov, W. Chu and P. Fongarland, Chem Rev, 2007, 107, 1692; W. Chu, P. A. Chernayskii, L. Gengembre, G. A. Pankina, P. Fongarland and A. Y. Khodakov, J Catal, 2007, 252, 215, both of which are incorporated by reference). The X-ray diffraction patterns were measured and collected on an XRD Bruker D8 diffractometer with Cu Ka radiation. Transmission electron microscopy (TEM) images were obtained from a JEOL JEM-2000 FX microscope at 200 kV in National University of Singapore (NUS). The samples were prepared by ultrasonic dispersion in an ethanol solution, placed on a copper TEM grid, and evaporated. Scanning electron microscope (SEM) images were obtained on a Philips FEG XL-30 system. Room temperature micro-Raman scattering analyses were carried out with a Renishaw spectrometer using Ar laser excitation source. The FT-IR spectra of the samples were measured using the KBr wafer in a Bruker Tensor 27 FT-IR spectrometer. The spectra were recorded in the range of 400-4000 cm⁻¹. TG-DTG was performed to characterize their decomposition behavior and peak temperature for the carbon nanotubes sample, while the air was used as the carrier gas for reacting the sample with a heating rate at 20° C./min in the temperature range 500-800° C.

Both of the CVD-IP1 and CVD-IP2 processes resulted in a very efficient conversion of carbon dioxide to carbon nanotubes. The productions of CNT-C1 and CNT-C2 samples at a high single-pass productivity are illustrated in Table 2. In particular, starting from 150 mg catalyst reacting at 650° C. for 270 minutes (at inlet CO₂ flowrate of 15 ml/min), 948 mg carbon nanotubes were ultimately produced and the carbon nanotubes productivity was 632% (the ratio of CNTs mass over that of catalyst) for both the CVD-IP1 and CVD-IP2 processes. Further, the single-pass yields of solid-form carbon product carbon nanotubes produced from the CVD-IP1 and CVD-IP2 processes were 29.4% and 31.5% respectively at a single-pass carbon-base. For comparison, when only pure carbon dioxide was introduced without hydrogen using the conventional CVD method (Wen et al. 2010), no solid-state carbon nanotubes product was formed. Further, introducing pure carbon dioxide as a feed without introducing hydrogen in the CVD-IP system also resulted in no carbon nanotubes production, which is illustrated in Table 2.

TABLE 2
MWCNTs production at different conditions (Cp01, Expt 11-14#)

| | | CNT | C-based |
|---|---|---|---|
| | | productivity | CNT yield |
| Sample Code | Rn Temp. (° C.) | (g/g catal, %) | (%) |
| Comparative test 1 | (a) 650 | 0 | 0 |
| (Cp01#) | | | |
| Comparative test 2 | (a) 650 | 396 | 12.3 |
| (Cp02# CNT-M1) | | | |
| Ex 11 (CNT-C1) | (a) 650 | 632 | 29.4 |
| Ex 12 (CNT-C2) | (b) 650 C. + vapor | 773 | 31.5 |
| Ex 13 (CNT-C3) | (a) 750 | 775 | 36.2 |
| Ex 14 (CNT-C4) | (b) 750 C. + vapor | 820 | 38.3 |

(a) without water at 650° C. or 750° C., 270 minutes; CO₂ = 15 ccm.
(b) with water vapor at 650° C. or 750° C., 270 minutes; CO₂ = 15 ccm.

The TEM images of the CO₂-derived CNTs (CNT-C1) are provided in FIG. 2. Mainly straight carbon nanotubes (FIG. 2b) were produced. Further, the majority of the ends of the carbon nanotubes were closed/caped. By comparison, when water vapor was added to the process (CVD-IP2), the majority of the CNTs (CNT-C2) had opened/un-capped ends. Open-ended tubes can be desirable in many application due to defined-filed effects (see W. Chen, X. L. Pan and X. H. Bao, J Am Chem Soc, 2007, 129, 7421; X. L. Pan and X. H. Bao, Chem Commun, 2008, 6271; X. L. Pan, Z. L. Fan, W. Chen, Y. J. Ding, H. Y. Luo and X. H. Bao, Nat Mater, 2007, 6, 507, each of which is incorporated by reference).

The representative transmission electron microscope (TEM)/HRTEM images of CNT-C1 and CNT-C2 carbon nanotubes were analyzed respectively. CNT-C1 carbon nanotubes displayed a “bamboo-like” morphology (FIG. 2). Greater magnification confirms the presence of straight carbon nanotubes (FIG. 2(b)) while the carbon nanotube ends were mostly closed/capped. It was also seen from the high magnification TEM image that the outer diameter of the CNT-C1 carbon nanotubes were about 20 nm with wall thicknesses ranging from 5 to 6 nm and inner diameters in the range of about 7-10 nm.

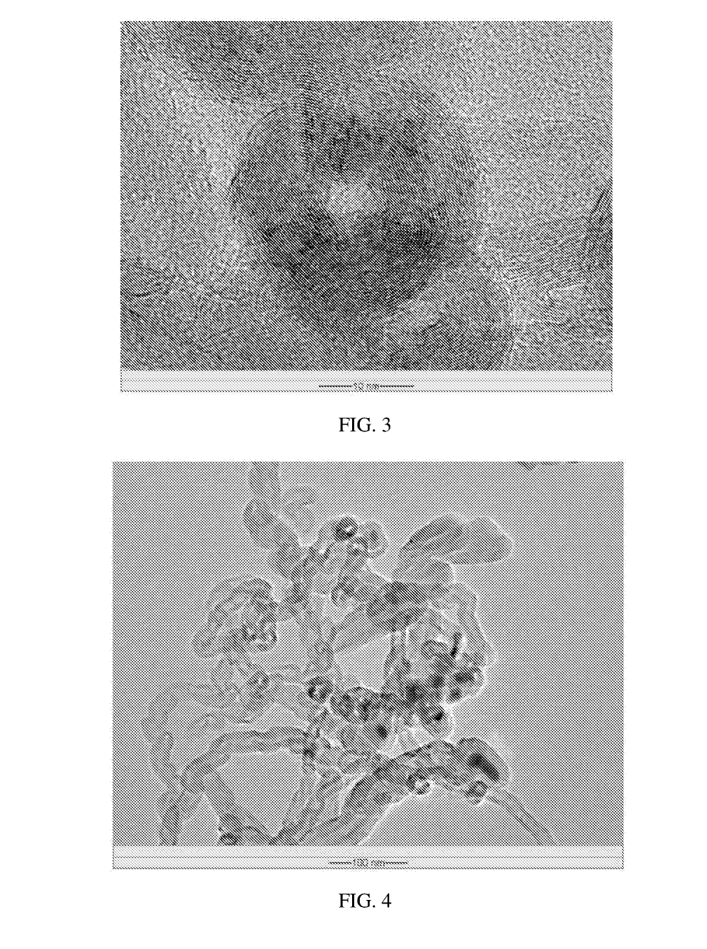

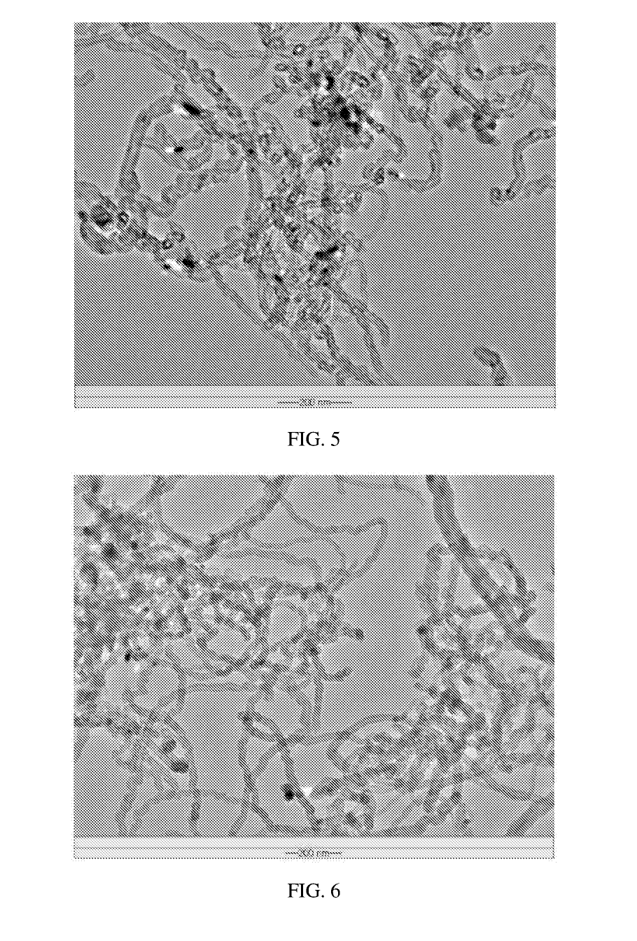

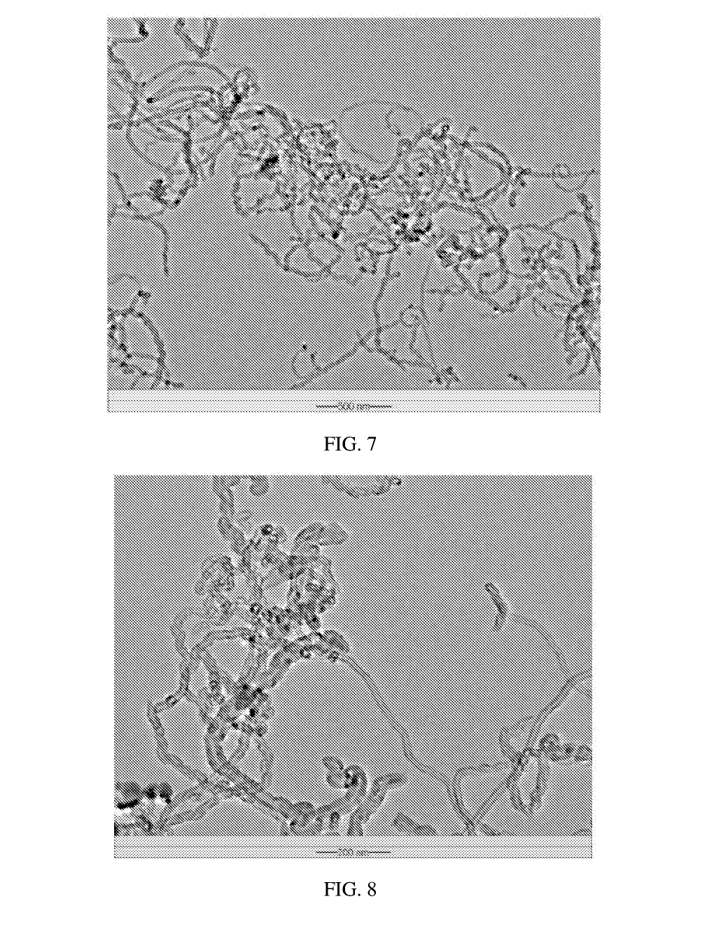

The SEM & TEM images of CO₂-derived CNT-C2 carbon nanotubes were analyzed and compared. The SEM morphology of CNT-C2 carbon nanotubes in meso-scale is similar to that of the SEM image for the CO₂-derived CNT-C1 carbon nanotubes. However, a primary difference is that a large part of the CNT-C2 carbon nanotubes had opened/un-capped ends (shown in FIG. 3-FIG. 8), whereas the CNT-C1 carbon nanotubes had closed/capped ends. FIG. 3 also shows that the carbon nanotubes included twenty-four graphene layers with outer diameters of about 20 nm, an inner diameters of about 4 nm and wall thicknesses of about 8 nm. Therefore, the distance between graphene layers was estimated to about 0.3 nm. Further, TEM and HRTEM images of the CNT-C2 nanotubes of different magnification times are provided in FIGS. 3-8.

The XRD patterns of CO₂-derived CNT-C1 and CNT-C2 carbon nanotubes were analyzed, together with that of a conventional carbon nanotubes (CNT-M1 sample). There are two typical diffraction peaks at 26.0° and 42.90° two theta, which are due to the (002) and (100) reflections of graphite carbon respectively, corresponding to SP2-hybrid graphene carbon. These two peaks can also be seen from sample CNT-M1, but with a slightly lower peak density. The other diffractions peaks were due to metallic nickel and magnesium oxide, which was used as the support for the nickel catalyst, on which the CNTs grew (see C. Emmenegger, J. M. Bonard, P. Mauron, P. Sudan, A. Lepora, B. Grobety, A. Zuttel and L. Schlapbach, Carbon, 2003, 41, 539, which is incorporated by reference).

The Raman spectrum of sample CNT-C2 was analyzed and discussed. The two peaks at 1342 cm⁻¹ and 1571 cm⁻¹ were assigned to the D and G bands of the CNTs, respectively (see Q. Wen, W. Z. Qian, F. Wei, Y. Liu, G. Q. Ning and Q. Zhang, Chem Mater, 2007, 19, 1226, which is incorporated by reference). The intensity ratio (ID/IG) of the D band over the G band was utilized to evaluate the perfection of the synthesized CNTs. The ID/IG value of sample CNT-C2 was 0.907, indicating that the sample was Multi-wall carbon nanotubes (MWCNTs) (see Wen et al. 2007).

The TG-DTG curves of three samples were compared and discussed, for CO₂-derived CNT-C1, and CNT-C2 carbon nanotubes as well as the conventional CNT-M1 nanotubes. The weight loss of the three samples after increasing the temperature to 800° C. was about 85 wt %. There were only slight differences of weight loss for these three samples. From the DTG curves, it can be seen that there is a single peak of weight loss, which occurred at around 690° C. (see W. Huang, Y. Wang, G. H. Luo and F. Wei, Carbon, 2003, 41, 2585, which is incorporated by reference), which was due to the oxidation of graphite carbon, further supporting that the samples only consisted of graphene carbon. No weight loss event is seen at about 400° C., indicating that the carbon nanotubes did not contain amorphous carbon (see Huang et al., 2003). The above TG-DTG results demonstrated that the quality of the CNTs produced using CO₂ as the sole carbon source is comparable to that produced from pure methane raw material.

The FT-IR spectra of these samples in the wavelength range of 1000-2000 cm⁻¹ were compared. The main peak at 1630 cm was due to the surface carbonyl. In addition, two more absorption bands at 1440 cm⁻¹ and 1720 cm⁻¹ can be seen for the CNT-C2 and CNT-M2 carbon nanotubes. The two absorption peaks were owing to the bending vibration of hydroxyl in carboxylic acids and phenolic groups and the carbonyl C═O species in —COOH, respectively (see H. M. Yang and P. H. Liao, Appl Catal a-Gen, 2007, 317, 226; C. H. Li, K. F. Yao and J. Liang, Carbon, 2003, 41, 858, each of which are incorporated by reference), indicating that the acid treatment (CNT-M2) and the presence of the water vapor (CNT-C2) led to the formation of surface groups in the CNTs. The formation of oxygen-containing groups, such as hydroxyl and —COOH was owing to the reaction between surface carbon atoms with the strong acid or the additive water vapor. The presence of such surface oxygen-containing groups can play a role in the new catalysts preparation (see W. Chen, X. L. Pan and X. H. Bao, J Am Chem Soc, 2007, 129, 7421, which is incorporated by reference). These above results demonstrated that the added water vapor functioned as that of nitric acid in terms of creation of surface functional groups on CNTs. Further, this process resulted in a more cost efficient, easier, and cleaner process when compared with the use nitric acid. Further, there was not a vibration band at 1550 cm⁻¹ (characteristic of carbon black (see Yang and Liao (2007))) for the samples, in good agreement with the results of TEM and TG-DTG data.

These above data confirm that there was relatively high CNTs productivity from carbon dioxide for the CVD-IP1 and CVD-IP2 processes, which utilized carbon dioxide as the sole source of carbon for producing carbon nanotubes (CNT-C1 and CNT-C2), (the CO₂ conversion was nearly 100%, and the solid-state carbon-product yield was more than 30% at a single-pass of each process).

### Example 3

### Nickel Catalyst System (Ni-A303) for the CVD-IP Process of MWCNTs Production from Carbon Dioxide and Effects of Reaction Temperature for CVD Process

For the preparation of another nickel containing catalyst, Ni-A303, the sample precursor was dried at 110° C. for 12 hours (h), and then calcined at 700° C. for 6 h. The second reaction (CVD process) was operated at a temperature in the range of 600° C. to 800° C. (Expt. 15-19).

To grow nanotubes, the two-step integrated CVD-IP new process has been utilized. Typically, 150 mg CVD catalyst (Ni-A303) in a ceramic boat was placed in the quartz reactor 2, followed by a reduction in pure H₂ at 550 C for 60 minutes. Then the CO₂/H₂ mixed gas was feed in the integrated process system. The carbon nanotube (MWCNTs) production was performed at different reaction temperature (at one temperature in the range of 600° C. to 800° C.). The inlet carbon dioxide was fixed at a flow rate of 30 ml/min, the MWCNTs growth process lasted for 120 minutes (two hours), then the furnace was cooled to room temperature under argon protection (Expt 15-19).

Another-type experiment was carried out using the same reactant feed and flowrate, however, the gas flow passed through a water bubbler at room temperature (23° C.) before entering the second reactor. The inlet carbon dioxide was fixed at a flow rate of 30 ml/min, (Expt 20). The outlet effluents were analyzed on-line by a gas chromatograph (GC) with a TDX01 column and a thermal conductivity detector (TCD).

The percentage of carbon productivity was defined as follows:

CNTs Productivity (%)=(M total−M catal)/M catal×100

where M total denoted the total weight of the solid-form carbon product and catalyst mixture after 120 minutes reaction, M catal was the weight of the catalyst before reaction. The effect of different reaction temperature ranging from 600 to 800° C. on the MWCNTs production was investigated.

The CNTs productivity and C-based MWCNT yield versus reaction temperature over catalyst Ni-A303 were illustrated in Table 3. As expected, the reaction temperature affected significantly the catalyst performance for CNTs production. The carbon yield increased with the rising of reaction temperature from 600° C. to 700° C. The CNTs productivity reached 530% at 700° C., possessing the higher catalytic activity. However, it decreased when the reaction temperature was increased further to 750-800° C. The lower CNTs productivity (245%) was obtained at 800° C. Therefore, 700° C. was selected as the optimal reaction temperature to evaluate the effect of water vapor addition on the CNTs productivity. From the result in Table 3 (Expt. 20), the MWCNTs productivity increased to 610% by introducing water vapor, which was 15% higher than that of water-free process. Therefore, CNTs growth could be enhanced by introducing small amount of water together with the CO₂-derived carbon source.

TABLE 3
(MWCNTs production at different conditions (Expt. 15-Expt. 20)

| | | CNT | |
|---|---|---|---|
| | Rn Temp. | productivity | C-based CNT yield |
| Expt. Code | (° C.) | (g/g catal, %) | (%) # |
| Ex 15 (a15) | 600 | 360 | 28.0 |
| Ex 16 (a16) | 650 | 385 | 29.9 |
| Ex 17 (a17) | 700 | 530 | 41.2 |
| Ex 18 (a18) | 750 | 320 | 24.9 |
| Ex 19 (a19) | 800 | 245 | 19.1 |
| Ex 20 (b20) | (b) 700 C. + vapor | 610 | 47.4 |

a) without water at different temperature,
(b) with water vapor at 700 C. Key:
#C-based CNTs yield is the ratio of carbon molar amount in carbon nanotube over the carbon molar amount of inlet carbon dioxide in percentage.

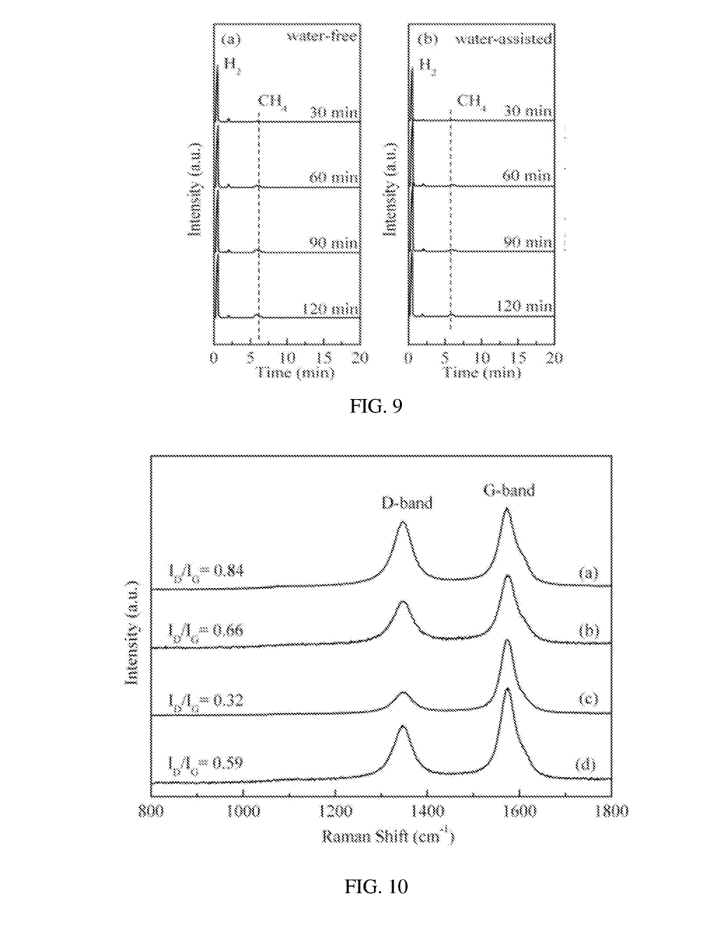

The GC profiles of gas-phase outlet mixture vs reaction time on stream in the CVD-IP process at 700° C. were shown in FIG. 9(a) and FIG. 9(b). It was shown that the amount of remained intermediate methane from carbon dioxide increased with the reaction time on stream, indicating that there was a slight decrease of CVD catalyst activity with the time on stream. There was no CO₂ peak for all these eight sampling in the GC analysis, which revealed that the inlet carbon dioxide was converted into intermediate methane nearly 100%.

### Example 4

### Raman & SEM Characterizations of Produced MWCNTs Using Ni-A3-LaOx

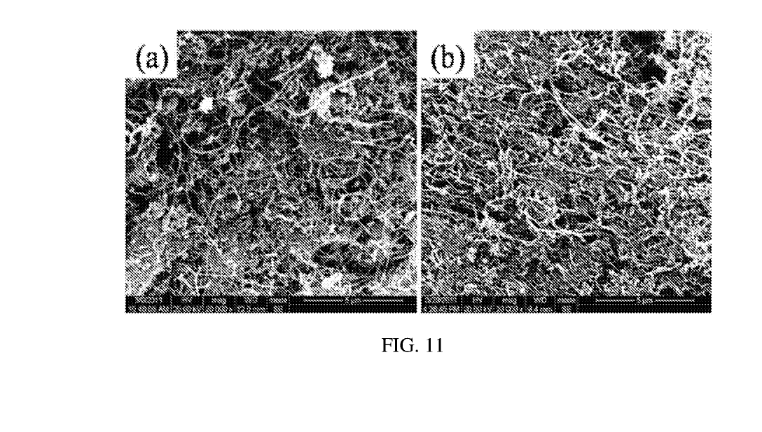

The Raman spectra of the CNTs samples were illustrated in FIG. 10. The band appearing at a wavenumber ca. 1575 cm⁻¹ was designated to the G band (graphite band), and the other band, at the wavenumber ca. 1348 cm⁻¹, was designated to the D band. The D band was related to the defects on the structure of CNTs. The relative intensity ratio of the D band to the G band (ID/IG) was normally used for the qualitative estimation of the defect degree of the CNTs. With the reaction temperature increasing from 600 to 800° C., the produced CNTs samples on the Ni-A303 catalyst showed a decreasing and smaller ID/IG ratio, 0.84 at 600° C., 0.66 at 700° C., 0.32 at 800° C., respectively. This result revealed that the high reaction temperature enhanced the formation of better graphitized CNTs. It was observed the ID/IG ratio of the water-assisted CNTs was 0.58, which was lower than that of water-free CNTs (ID/IG=0.66). This indicated that the water-assisted grown of CNTs over the sample saw slightly higher graphitic degree. The SEM micrographs for CNTs produced using the CVD-IP method were shown in FIG. 11. The CNTs samples were obtained with length in the range of tens of micrometer and diameter in the range of tens of nanometer. The water-free process CNTs samples gave higher carbon defects (or less-ordered in the morphology). The SEM micrograph for CNTs samples produced using the water-assisted CVD-IP method showed more ordered and enhanced morphology.

The methods for making carbon nanotubes and carbon nanotubes disclosed herein include at least the following embodiments:

### Embodiment 1

A method for making carbon nanotubes comprising: (a) reducing a nickel containing catalyst with a reducing agent in a first reaction chamber; (b) contacting the nickel containing catalyst with carbon dioxide under conditions sufficient to produce a reaction product; (c) transferring the reaction product to a second reaction chamber, wherein the second reaction chamber comprises a Group VIII metal containing catalyst; and (d) contacting the Group VIII metal containing catalyst with the reaction product under conditions sufficient to produce carbon nanotubes, wherein the first and second reaction chambers are in flow connection during the transfer step (c), wherein the only source of carbon used to form the carbon nanotubes is from the carbon dioxide used in step (b), and wherein at least 20% of the carbon from the carbon dioxide used in step (b) is converted into carbon nanotubes.

### Embodiment 2

The method of embodiment 1, wherein the reducing agent is hydrogen gas.

### Embodiment 3

The method of any one of embodiments 1-2, wherein the nickel containing catalyst is supported by a metal oxide or oxide carrier.

### Embodiment 4

The method of embodiment 3, wherein the metal oxide is selected from the group consisting of: silicon dioxide; aluminum oxide; a rare earth metal oxide; a modified aluminum oxide; and mixtures thereof.

### Embodiment 5

The method of embodiment 3, wherein the oxide carrier is selected from the group consisting of magnesium oxide, calcium oxide, other alkali-earth oxide, zinc oxide, zirconium oxide, titanium oxide, and mixture thereof.

### Embodiment 6

The method of any one of embodiments 1-5, wherein the Group VIII metal containing catalyst is a nickel, cobalt, or iron containing catalyst or a composite thereof.

### Embodiment 7

The method of any one of embodiments 1-6, wherein step (b) is performed in the presence of hydrogen.

### Embodiment 8

The method of any one of embodiments 1-6, wherein the reaction product comprises methane.

### Embodiment 9

The method of embodiment 8, wherein the reaction product further comprises water, carbon dioxide, hydrogen, or carbon monoxide.

### Embodiment 10

The method of any one of embodiments 1-9, wherein step (b) is performed at a temperature ranging from about 260° C. to about 460° C., or from about 300° C. to about 380° C.

### Embodiment 11

The method of any one of embodiments 1-10, wherein step (d) is performed at a temperature ranging from about 600° C. to about 800° C. or from about 650° C. to about 750° C.

### Embodiment 12

The method of any one of embodiments 1-11, wherein the carbon dioxide is introduced into the first reaction chamber at a flow rate of about 5 ml/min to about 60 ml/min.

### Embodiment 13

The method of any one of embodiments 1-12, wherein the carbon nanotubes are multi-wall or single-wall carbon nanotubes or a combination thereof.

### Embodiment 14

The method of any one of embodiments 1-13, wherein the majority of the carbon nanotubes have closed tube ends.

### Embodiment 15

The method of embodiment 14, wherein the outer diameter of the carbon nanotubes ranges from about 19 nm to about 21 nm, the thickness of the carbon nanotube walls range from about 4 nm to about 7 nm, and the inner diameter of the carbon nanotubes range from about 7 nm to about 10 nm.

### Embodiment 16

The method of any one of embodiments 1-15, wherein the reaction product is fed through water vapor.

### Embodiment 17

The method of embodiment 16, wherein the reaction product is fed through water vapor during any one of steps (b), (c), or (d), or prior to the reaction product being transferred to the second reaction chamber.

### Embodiment 18

The method of embodiment 17, wherein the water vapor pressure is about 1 kPa to about 10 kPa or about 1 kPa to about 5 kPa.

### Embodiment 19

The method of any one of embodiments 16-18, wherein the amount of water present within the reaction product after said product is fed through the water vapor is about 1% to about 10% or about 1% to about 5% by molar volume of the reaction product.

### Embodiment 20

The method of any one of embodiments 16-18, wherein at least part of the carbon nanotubes have open tube ends.

### Embodiment 21

The method of embodiment 20, wherein the carbon nanotubes are multi-wall carbon nanotubes.

### Embodiment 22

The method of embodiment 21, wherein the outer diameter of the carbon nanotubes ranges from about 19 nm to about 21 nm, the thickness of the carbon nanotube walls range from about 7 nm to about 9 nm, and the inner diameter of the carbon nanotubes range from about 3 nm to about 5 nm.

### Embodiment 23

The method of any one of embodiments 1-22, wherein at least 80%, 90%, 95%, or nearly 100% of the carbon dioxide used in step (b) was converted to the reaction product comprising multiple wall carbon nanotubes.

### Embodiment 24

The method of any one of embodiments 1-23, wherein carbon-based carbon nanotubes yield was at least 20% or more (e.g., 20%, 30%, 40% or more) from the carbon of the inlet carbon dioxide utilized in step (b).

### Embodiment 25

The method of any one of embodiments 1-24, wherein the carbon dioxide in step (b) is the only carbon source that is used to produce the carbon nanotubes.

### Embodiment 26

A carbon nanotube produced by the method of anyone of embodiments 1-25.

This written description uses examples to disclose the invention, including the best mode, and also to enable any person skilled in the art to make and use the invention. The patentable scope of the invention is defined by the claims, and may include other examples that occur to those skilled in the art. Such other examples are intended to be within the scope of the claims if they have structural elements that do not differ from the literal language of the claims, or if they include equivalent structural elements with insubstantial differences from the literal language of the claims.

All ranges disclosed herein are inclusive of the endpoints, and the endpoints are independently combinable with each other (e.g., ranges of “up to 25 wt. % or, more specifically, 5 wt. % to 20 wt. %”, is inclusive of the endpoints and all intermediate values of the ranges of “5 wt. % to 25 wt. %,” etc.). “Combination” is inclusive of blends, mixtures, alloys, reaction products, and the like. Furthermore, the terms “first,” “second,” and the like, herein do not denote any order, quantity, or importance, but rather are used to denote one element from another. The terms “a” and “an” and “the” herein do not denote a limitation of quantity, and are to be construed to cover both the singular and the plural, unless otherwise indicated herein or clearly contradicted by context. The suffix “(s)” as used herein is intended to include both the singular and the plural of the term that it modifies, thereby including one or more of that term (e.g., the film(s) includes one or more films). Reference throughout the specification to “one embodiment”, “another embodiment”, “an embodiment”, and so forth, means that a particular element (e.g., feature, structure, and/or characteristic) described in connection with the embodiment is included in at least one embodiment described herein, and may or may not be present in other embodiments. In addition, it is to be understood that the described elements may be combined in any suitable manner in the various embodiments. As used herein, “substantially” generally refers to less than 100%, but generally, greater than or equal to 50%, specifically, greater than or equal to 75%, more specifically, greater than or equal to 80%, and even more specifically, greater than or equal to 90%.

While particular embodiments have been described, alternatives, modifications, variations, improvements, and substantial equivalents that are or may be presently unforeseen may arise to applicants or others skilled in the art. Accordingly, the appended claims as filed and as they may be amended are intended to embrace all such alternatives, modifications, variations, improvements, and substantial equivalents.

What is claimed is:

1. A method for making carbon nanotubes comprising:
(a) reducing a nickel containing catalyst with a reducing agent in a first reaction chamber;
(b) contacting the nickel containing catalyst with carbon dioxide under conditions sufficient to produce a reaction product;
(c) transferring the reaction product to a second reaction chamber, wherein the second reaction chamber comprises a Group VIII metal containing catalyst; and
(d) contacting the Group VIII metal containing catalyst with the reaction product under conditions sufficient to produce carbon nanotubes,
wherein the first and second reaction chambers are in flow connection during the transfer step (c),
wherein the only source of carbon used to form the carbon nanotubes is from the carbon dioxide used in step (b), and
wherein at least 20% of the carbon from the carbon dioxide used in step (b) is converted into carbon nanotubes.

2. The method of claim 1, wherein the reducing agent is hydrogen gas.

3. The method of claim 1, wherein the nickel containing catalyst is supported by a metal oxide or oxide carrier.

4. The method of claim 3, wherein the metal oxide is selected from the group consisting of: silicon dioxide; aluminum oxide; a rare earth metal oxide; a modified aluminum oxide; and mixtures thereof or wherein the oxide carrier is selected from the group consisting of magnesium oxide, calcium oxide, other alkali-earth oxide, zinc oxide, zirconium oxide, titanium oxide, and mixture thereof.

5. (canceled)

6. The method of claim 1, wherein the Group VIII metal containing catalyst is a nickel, cobalt, or iron containing catalyst or a composite thereof.

7. The method of claim 14, wherein step (b) is performed in the presence of hydrogen.

8. The method of claim 1, wherein the reaction product comprises methane.

9. (canceled)

10. The method of claim 1, wherein step (b) is performed at a temperature ranging from about 260° C. to about 460° C. and wherein step (d) is performed at a temperature ranging from about 600° C. to about 800° C.

11. (canceled)

12. The method of claim 1, wherein the carbon dioxide is introduced into the first reaction chamber at a flow rate of about 5 ml/min to about 60 ml/min.

13. The method of claim 1, wherein the carbon nanotubes are multi-wall or single-wall carbon nanotubes or a combination thereof and wherein the majority of the carbon nanotubes have closed tube ends.

14. (canceled)

15. The method of claim 14, wherein the outer diameter of the carbon nanotubes ranges from about 19 nm to about 21 nm, the thickness of the carbon nanotube walls range from about 4 nm to about 7 nm, and the inner diameter of the carbon nanotubes range from about 7 nm to about 10 nm.

16. (canceled)

17. The method of claim 1, wherein the reaction product is fed through water vapor during any one of steps (b), (c), or (d), or prior to the reaction product being transferred to the second reaction chamber.

18. The method of claim 17, wherein the water vapor pressure is about 1 kPa to about 10 kPa and wherein the amount of water present within the reaction product after said product is fed through the water vapor is about 1% to about 10%.

19. (canceled)

20. The method of claim 16, wherein at least part of the carbon nanotubes have open tube ends and wherein the carbon nanotubes are multi-wall carbon nanotubes.

21. (canceled)

22. The method of claim 21, wherein the outer diameter of the carbon nanotubes ranges from about 19 nm to about 21 nm, the thickness of the carbon nanotube walls range from about 7 nm to about 9 nm, and the inner diameter of the carbon nanotubes range from about 3 nm to about 5 nm.

23. The method of claim 1, wherein at least 80% of the carbon dioxide used in step (b) was converted to the reaction product comprising multiple wall carbon nanotubes.

24. The method of claim 1, wherein carbon-based carbon nanotubes yield was at least 20% or more from the carbon of the inlet carbon dioxide utilized in step (b).

25. The method of claim 1, wherein the carbon dioxide in step (b) is the only carbon source that is used to produce the carbon nanotubes.

26. A carbon nanotube produced by the method of claim 1.
